(19) United States
(12) Patent Application Publication
(10) Pub. No.: US 2017/0362733 A1
(43) Pub. Date: Dec. 21, 2017

(54) COPPER FOIL WITH RELEASE LAYER, LAMINATED MATERIAL, METHOD FOR PRODUCING PRINTED WIRING BOARD, AND METHOD FOR PRODUCING ELECTRONIC APPARATUS

(71) Applicant: JX NIPPON MINING & METALS CORPORATION, Tokyo (JP)

(72) Inventor: MICHIYA KOHIKI, IBARAKI (JP)

(21) Appl. No.: 15/628,733

(22) Filed: Jun. 21, 2017

(30) Foreign Application Priority Data
Jun. 21, 2016 (JP) 2016-122842

(51) Int. Cl. C25D 7/06; C25D 1/04; B32B 15/08; B32B 15/20; H05K 3/02; C25D 5/12

(52) U.S. Cl. CPC C25D 7/0614; H05K 3/025; C25D 5/12; B32B 15/08; B32B 15/20; C25D 1/04

(57) ABSTRACT

A copper foil with a release layer is provided that capable of forming a circuit, of such as an embedded trace substrate, by a subtractive method in a simple process. A copper foil with a release layer, containing, in this order, a release layer; a barrier layer having dissolution resistance to a copper etchant; and a copper foil.

### TECHNICAL FIELD

The present invention relates to a copper foil with a release layer, a laminated material, a method for producing a printed wiring board, and a method for producing an electronic apparatus.

### BACKGROUND ART

Printed wiring boards have been largely evolved over the recent half century, and in these days, are used in most electronic equipment. Associated with the increasing needs of the miniaturization and performance enhancement of electronic equipments in recent years, the increase of the packaging density of mounted components and the increase of the signal frequency are progressing, and thus printed wiring boards are demanded to have a fine conductor pattern (i.e., a fine pitch pattern) and a capability to process high frequency signals. In particular, a fine pitch of L (line)/S (space)=20 mμ/20 μm or less is demanded for mounting an IC chip on a printed wiring board.

A printed wiring board is produced firstly as a copper-clad laminated material containing a copper foil that is adhered with an insulating substrate, which is represented mainly by a glass epoxy substrate, a BT resin, and a polyimide film. The method of adhesion used may be a method of forming by laminating the insulating substrate and the copper foil, which are then pressed under heating (i.e., a laminating method), or a method of coating a varnish, which is a precursor of the insulating substrate material, on a surface of the copper foil having a coated layer, and then curing the varnish by heating (i.e., a casting method).

Associated with the achievement of a fine pitch pattern, the foil thickness of the copper foil used in the copper-clad laminated material is being decreased to 9 μm, and further to μm or less. However, with the foil thickness of 9 μm or less, the handleability is considerably deteriorated in the formation of the copper-clad laminated material by the laminating method or the casting method. Under the circumstances, a metal foil with a carrier comes on the market, which utilizes a copper foil having a certain thickness as a carrier, having formed thereon an ultrathin copper layer through a release layer. The copper foil with a carrier is generally used in such a manner as described in PTL 1 and the like that the surface of the ultrathin copper layer is adhered to an insulating substrate, press adhesion is performed under heat, and the carrier is released through the release layer.

In the production of a printed wiring board using the copper foil with a carrier, the copper foil with a carrier is typically used in such a manner that the copper foil with a carrier is laminated on an insulating substrate, and the carrier is released from the ultrathin copper layer. A plating resist formed with a photocurable resin is then provided on the ultrathin copper layer having been exposed by releasing the carrier. The prescribed area of the plating resist is then exposed to light, so as to cure the area. Subsequently, the uncured resist in the non-exposed area is removed, and then an electroplated layer is provided in the area, from which the resist has been removed. Then, the cured plating resist is removed, thereby providing an insulating substrate having a circuit formed thereon, with which a printed wiring board is produced.

### CITATION LIST

### Patent Literature

[PTL 1] JP-A-2006-022406

### SUMMARY OF INVENTION

### Technical Problem

In recent years, various production methods of a printed wiring board have been developed and utilized depending on the purposes. For example, an embedded trace substrate (ETS) is produced, such as a printed wiring board produced by a so-called embedding method, in which a circuit plating is formed on a surface of an ultrathin copper layer of a copper foil with a carrier, an embedding resin is provided on the ultrathin copper layer to cover the formed circuit plating (i.e., to embed the circuit plating), so as to laminate a resin layer, holes are formed at prescribed positions of the resin layer to form blind via holes for exposing the circuit plating, and a circuit or a wiring is formed to conduct the plural layers of the laminated material.

In the embedded trace substrate or the like, a circuit is formed by copper plating on an ultrathin copper layer, and at this time, a circuit is formed in such a manner that a dry film (plating resist) is laminated on the ultrathin copper layer, and then exposed and developed to form copper plating (patterned copper plating), and then the dry film is released. However, the formation of a circuit with patterned copper plating in this manner complicates the process and causes a problem in cost.

### Solution to Problem

As a result of earnest investigations made by the present inventors, it has been found that by using a copper foil capable of forming a circuit by a subtractive method, after the lamination of the dry film (plating resist) and then the exposure and development thereof, a circuit can be formed by a subtractive method without formation of a circuit with patterned copper plating, and thus a circuit, such as an embedded trace substrate, can be produced by a simple process.

The present invention completed based on the aforementioned knowledge has the following features.

The present invention is a copper foil with a release layer, comprising, in this order, a release layer; a barrier layer having dissolution resistance to a copper etchant; and a copper foil.

In one embodiment of the present invention, the barrier layer having dissolution resistance to a copper etchant may be a layer having one or more layer selected from the group consisting of a Ni layer, a Ti layer, a Cr layer, a V layer, a Zr layer, a Ta layer, a Au layer, a Pt layer, an Os layer, a Pd layer, a Ru layer, a Rh layer, an Ir layer, a W layer, a Sn layer, a stainless steel layer, a Ag layer, a Mo layer, a Ni—Cr alloy layer, an Al layer, a Co layer, an In layer, a Bi layer, an ITO (indium tin oxide) layer; a layer containing an alloy containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, Bi, Sn, Ag, Mo, and Cr; and a layer containing a carbide, an oxide, or a nitride containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, Bi, Sn, Ag, Mo, and Cr.

In another embodiment of the present invention, the barrier layer having dissolution resistance to a copper etchant may be a Ni layer or an alloy layer containing Ni.

In another embodiment of the present invention, the release layer may have a silane compound represented by the following formula, a hydrolyzed product thereof, or a condensed product of the hydrolyzed product alone or in combination thereof:

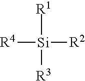

wherein R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; and R³ and R⁴ each independently represents a halogen atom, or an alkoxy group, a hydrocarbon group selected from the group consisting of an alkyl group, a cycloalkyl group, and an aryl group, or any of the hydrocarbon groups with at least one hydrogen atom substituted with a halogen atom.

In another embodiment of the present invention, the release layer may have a compound having two or less mercapto group in a molecule.

In another embodiment of the present invention, the release layer may have a single compound or a combination of plural compounds of an aluminate compound, a titanate compound, or a zirconate compound represented by the following formula, a hydrolyzed product thereof, or a condensed product of the hydrolyzed product:

(R¹)ₘ-M-(R²)ₙ

wherein R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; M represents any one of Al, Ti, and Zr; n represents 0, 1, or 2; and m represents an integer of 1 or more and a valence of M or less, provided that at least one of R¹ represents an alkoxy group, and m+n is a valence of M, i.e., 3 for Al, and 4 for Ti or Zr.

In another embodiment of the present invention, the release layer may have a resin coated film constituted by one or more resins selected from a silicone, an epoxy resin, a melamine resin, and a fluorine resin.

In another embodiment of the present invention, the copper foil may have one or more layer selected from the group consisting of a roughening treatment layer, a heat resistant layer, a rust preventing layer, a chromate treatment layer, and a silane coupling treatment layer, on a surface opposite to the release layer.

In another embodiment of the present invention, the roughening treatment layer may be a layer containing a single material selected from the group consisting of copper, nickel, phosphorus, tungsten, arsenic, molybdenum, chromium, titanium, iron, vanadium, cobalt, and zinc, or an alloy containing one or more thereof.

In another embodiment of the present invention, the copper foil may have a resin layer, on the one or more layer selected from the group consisting of a roughening treatment layer, a heat resistant layer, a rust preventing layer, a chromate treatment layer, and a silane coupling treatment layer.

In another embodiment of the present invention, the copper foil with a release layer may have a resin layer, on the copper foil.

Further, the present invention is a laminated material comprising the copper foil with a release layer.

Further, the present invention is a laminated material comprising the copper foil with a release layer and a resin, a part or the whole of an end surface of the copper foil with a release layer being covered with the resin.

Further, the present invention is a laminated material comprising the two copper foils with a release layer and a resin, the resin being provided in such a manner that a surface of one copper foil with a release layer of the two copper foils with a release layer on the side of the copper foil and a surface of the other copper foil with a release layer thereof on the side of the copper foil each are exposed.

Further, the present invention is a laminated material comprising one of the copper foil with a release layer, being laminated on the side of the copper foil of another copper foil with a release layer.

Further, the present invention is a method for producing a printed wiring board, comprising producing a printed wiring board by using the copper foil with a release layer.

Further, the present invention is a method for producing a printed wiring board, comprising:

laminating an insulating substrate 1 on the copper foil with a release layer, on the side of the release layer;

laminating a dry film on the copper foil with a release layer of the invention having the insulating substrate 1 laminated thereon, on the side of the copper foil;

patterning the dry film, and then etching the copper foil, so as to form a circuit;

releasing the dry film, so as to expose the circuit;

covering the exposed circuit with an insulating substrate 2, so as to embed the circuit;

releasing the insulating substrate 1 from a laminated material of the circuit embedded in the insulating substrate 2 and a barrier layer, through the release layer, so as to expose the barrier layer; and

removing the exposed barrier layer by etching, so as to expose the circuit embedded in the insulating substrate 2.

Furthermore, the present invention is a method for producing an electronic apparatus, comprising producing an electronic apparatus by using a printed wiring board produced by the method.

### Advantageous Effects

A copper foil with a release layer can be provided that is capable of forming a circuit, of such as an embedded trace substrate, by a subtractive method with a simple process.

### BRIEF DESCRIPTION OF DRAWING

FIGS. 1a-1i comprise a schematic illustration showing a method for forming an embedded circuit by using a copper foil with a release layer according to one embodiment of the invention.

### DESCRIPTION OF EMBODIMENTS

<Copper Foil with Release Layer>

The copper foil with a release layer of the invention contains, in this order, a release layer; a barrier layer having dissolution resistance to a copper etchant; and a copper foil. The copper foil may be provided typically in the form of a rolled copper foil or an electrolytic copper foil. In general, an electrolytic copper foil may be produced through electrolytic deposition of copper from a copper sulfate plating bath onto a titanium or stainless steel drum, and a rolled copper foil may be produced by repeating plastic forming with a mill roll and a heat treatment. The material used for the copper foil may be a high purity copper, such as a tough pitch copper (JIS H3100, alloy number: C1100) and an oxygen-free copper (JIS H3100, alloy number: C1020, or JIS H3510, alloy number: C1011), and may also be a copper alloy, such as a Sn-containing copper, a Ag-containing copper, a copper alloy containing Cr, Zr, or Mg, and a Corson copper alloy containing Ni, Si, and the like.

In the invention, the term “having dissolution resistance” means that the material is harder to be dissolved in a copper etchant (i.e., an etching solution for copper) or has a smaller rate of etching than copper.

The barrier layer having dissolution resistance to a copper etchant used is preferably a Ni layer, a Ti layer, a Cr layer, a V layer, a Zr layer, a Ta layer, an Au layer, a Pt layer, an Os layer, a Pd layer, a Ru layer, a Rh layer, an Ir layer, a W layer, a Sn layer, a stainless steel layer, a Ag layer, a Mo layer, a Ni—Cr alloy layer, an Al layer, a Co layer, an In layer, a Bi layer, an ITO (indium tin oxide) layer; a layer containing an alloy containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, Bi, Sn, Ag, Mo, and Cr; or a layer containing a carbide, an oxide, or a nitride containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, Bi, Sn, Ag, Mo, and Cr. The barrier layer having dissolution resistance to a copper etchant used is more preferably a Ni layer, a Ti layer, a Cr layer, a V layer, a Zr layer, a Ta layer, an Au layer, a Pt layer, an Os layer, a Pd layer, a Ru layer, a Rh layer, an Ir layer, a W layer; a layer containing an alloy containing one or more element selected from the group consisting of Ni, Ti, V, Zr, Ta, Au, Pt, Os, Pd, Ru, Rh, Ir, W, Si, and Cr; or a layer containing a carbide, an oxide, or a nitride containing one or more element selected from the group consisting of Ni, Ti, V, Zr, Ta, Au, Pt, Os, Pd, Ru, Rh, Ir, W, Si, and Cr. The barrier layer having dissolution resistance to a copper etchant used is furthermore preferably a Ni layer or an alloy layer containing Ni.

The Ni layer or the alloy layer containing Ni is preferably formed in the following manner. This is since the surface of the Ni layer or the alloy layer containing Ni becomes smooth, and thus surfaces of an ultrathin copper layer and/or a copper layer formed thereon, on the side of the barrier layer and the side opposite to the barrier layer become smooth, thereby enhancing the fine circuit formability of the ultrathin copper layer and/or the copper layer.

### Formation of Ni Layer or Alloy Layer Containing Ni

The Ni layer or the alloy layer containing Ni may be formed by performing nickel plating or alloy plating containing nickel. At this time, it is important to finish dense and uniform plating with no defect. The nickel plating or the alloy plating containing nickel may be performed in the following conditions.

### Plating Solution

Nickel: 20 to 200 g/L

Other elements: 0.1 to 200 g/L (only for the alloy plating containing nickel)

Boric acid: 5 to 60 g/L

Liquid temperature: 40 to 65° C.

pH: 1.5 to 5.0, preferably 2.0 to 3.0

By performing the plating treatment stepwise with relatively lower pH, hydrogen gas is formed to make a reducing atmosphere on the surface of the cathode. Accordingly, the factor forming water, such as an oxide, a hydroxide, and a hydrate, can be suppressed from occurring.

Current density: 0.5 to 20 A/dm², preferably 2 to 8 A/m²

The treatment is preferably performed at a low current density since burned plating is hard to occur, and dense plating with less defects can be formed.

Agitation (liquid circulation amount): 100 to 1,000 L/min

A larger liquid circulation amount may enhance the gas release of formed hydrogen gas, and decrease of the defects, such as pinholes. Furthermore, an effect of decreasing the diffusion layer thickness, and the factor forming water, such as a hydroxide, can be suppressed from occurring.

Conveying speed of object to be plated: 2 to 30 m/min, preferably 5 to 10 m/min

A lower conveying speed may form the Ni layer or the alloy layer containing nickel that is smooth and dense.

Additives

A primary gloss agent and a secondary gloss agent shown below are preferably used as additives. According to the use thereof, the crystals may be smooth and dense, and thus the defects formed in plating may be decreased to decrease the water uptake amount.

(Primary Gloss Agent)

Any one of sodium 1,5-naphthalenedisulfonate: 2 to 10 g/L, sodium 1,3,6-naphthalenetrisulfonate: 10 to 30 g/L, p-toluenesulfonamide: 0.5 to 4 g/L, and sodium saccharin: 0.5 to 5 g/L

(Secondary Gloss Agent)

Any one of formalin: 0.5 to 5 g/L, gelatin: 0.005 to 0.5 g/L, thiourea: 0.05 to 1.0 g/L, propargyl alcohol: 0.01 to 0.3 g/L, 1,4-butinediol: 0.05 to 0.5 g/L, and ethylene cyanohydrin: 0.05 to 0.5 g/L

The ordinary copper foil with a release layer does not have a barrier layer having dissolution resistance to a copper etchant, and there has been no example of the copper foil with a release layer applied to the embedding method. It is considered that this is since there is danger of corrosion up to the release layer by etching. On the other hand, the copper foil with a release layer of the invention has a barrier layer having dissolution resistance to a copper etchant between the copper foil and the release layer, and therefore there is no danger of corrosion up to the release layer by etching. Accordingly, the release layer can exhibit the function thereof in the formation of a circuit by the subtractive method in the embedding method. Consequently, in the formation of an embedded circuit using the copper foil with a release layer, a circuit can be formed by a subtractive method without the formation of a circuit with patterned copper plating, after the lamination of the dry film (plating resist) and then the exposure and development thereof, and thus a circuit, such as an embedded trace substrate, can be produced by a simple process.

The release layer will be described. When a resin substrate is adhered to the side of the release layer by pressing or the like, the release layer of the copper foil with a release layer enables release of the resin substrate. At this time, the resin substrate and the copper foil are released from each other through the release layer. When the resin substrate is adhered to the side of the release layer of the copper foil with a release layer, the peel strength between the resin substrate and the copper foil with a release layer is not particularly limited. When the resin substrate is adhered to the side of the release layer of the copper foil with a release layer, the peel strength between the resin substrate and the copper foil with a release layer is preferably 1 gf/cm or more, more preferably 3 gf/cm or more, furthermore preferably 5 gf/cm. Also, when the resin substrate is adhered to the side of the release layer of the copper foil with a release layer, the peel strength between the resin substrate and the copper foil with a release layer is preferably 500 gf/cm or less, preferably 200 gf/cm or less, more preferably 150 gf/cm or less, furthermore preferably 100 gf/cm or less. Further, when the resin substrate is adhered to the side of the release layer of the copper foil with a release layer and is then heated at 220° C. for at least one period selected from 3, 6 or 9 hours, the peel strength between the resin substrate and the copper foil with a release layer is preferably 1 gf/cm or more, more preferably 3 gf/cm or more, furthermore preferably 5 gf/cm. Furthermore, when the resin substrate is adhered to the side of the release layer of the copper foil with a release layer and is then heated at 220° C. for at least one period selected from 3, 6 or 9 hours, the peel strength between the resin substrate and the copper foil with a release layer is preferably 500 gf/cm or less, preferably 200 gf/cm or less, more preferably 150 gf/cm or less, furthermore preferably 100 gf/cm or less. When the resin substrate is adhered to the side of the release layer of the copper foil with a release layer, the productivity can be improved by controlling the peel strength between the resin substrate and the copper foil with a release layer to the above range.

### (1) Silane Compound

The release layer may be formed of a single compound or a combination of plural compounds of a silane compound having a structure represented by the following formula, a hydrolyzed product thereof, or a condensed product of the hydrolyzed product.

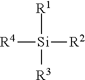

In the formula, R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; and R³ and R⁴ each independently represents a halogen atom, or an alkoky group, a hydrocarbon group selected from the group consisting of an alkyl group, a cycloalkyl group, and an aryl group, or any of the hydrocarbon groups with at least one hydrogen atom substituted with a halogen atom.

The silane compound preferably has at least one alkoxy group. In the case where the substituents are constituted only by a hydrocarbon group selected from the group consisting of an alkyl group, a cycloalkyl group, and an aryl group, or any of the hydrocarbon groups with at least one hydrogen atom substituted with a halogen atom, with no alkoxy group present, the adhesiveness between the plate carrier and the surface of the metal foil tends to be decreased excessively. Furthermore, the silane compound preferably has at least one hydrocarbon group selected from the group consisting of an alkyl group, a cycloalkyl group, and an aryl group, or any of the hydrocarbon groups with at least one hydrogen atom substituted with a halogen atom. In the case where the hydrocarbon group is not present, the adhesiveness between the plate carrier and the surface of the metal foil tends to be increased. The alkoxy group referred in the invention includes an alkoxy group with at least one hydrogen atom substituted with a halogen atom.

The silane compound preferably has three alkoxy groups and one of the hydrocarbon group (including the hydrocarbon group with at least one hydrogen atom substituted with a halogen atom). This means that in the aforementioned formula, R³ and R⁴ each preferably represent an alkoxy group.

The alkoxy group is not limited, and examples thereof include a linear, branched, or cyclic alkoxy group having from 1 to 20 carbon atoms, preferably having from 1 to 10 carbon atoms, and more preferably having from 1 to 5 carbon atoms, such as a methoxy group, an ethoxy group, a n- or iso-propoxy group, a n-, iso-, or tert-butoxy group, a n-, iso-, or neo-pentoxy group, a n-hexyloxy group, a cyclohexyloxy group, a n-heptyloxy group, and a n-octyloxy group.

Examples of the halogen atom include a fluorine atom, a chlorine atom, a bromine atom, and an iodine atom.

The alkyl group is not limited, and examples thereof include a linear or branched alkyl group having from 1 to 20 carbon atoms, preferably having from 1 to 10 carbon atoms, and more preferably having from 1 to 5 carbon atoms, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having from 3 to 10 carbon atoms, and preferably having from 5 to 7 carbon atoms, such as a cyclopropyl group, a cyclobutyl group, a cyclopentyl group, a cyclohexyl group, a cycloheptyl group, and a cyclooctyl group.

Examples of the aryl group include an aryl group having from 6 to 20 carbon atoms, and preferably having from 6 to 14 carbon atoms, such as a phenyl group, a phenyl group substituted with an alkyl group (e.g., a tolyl group and a xylyl group), a 1- or 2-naphthyl group, and an anthryl group.

The hydrocarbon group may have at least one hydrogen atom that is substituted with a halogen atom, for example, substituted with a fluorine atom, a chlorine atom, or a bromine atom.

Preferred examples of the silane compound include methyltrimethoxysilane, ethyltrimethoxysilane, n- or iso-propyltrimethoxysilane, n-, iso-, or tert-butyltrimethoxysilane, n-iso-, or neo-pentyltrimethoxysilane, hexyltrimethoxysilane, octyltrimethoxysilane, decyltrimethoxysilane, phenyltrimethoxysilane, an alkyl-substituted phenyltrimethoxysilane (such as p-(methyl)phenyltrimethoxysilane), methyltriethoxysilane, ethyltriethoxysilane, n- or iso-propyltriethoxysilane, n-, iso-, or tert-butyltriethoxysilane, pentyltriethoxysilane, hexyltriethoxysilane, octyltriethoxysilane, decyltriethoxysilane, phenyltriethoxysilane, an alkyl-substituted phenyltriethoxysilane (such as p-(methyl)phenyltriethoxysilane), (3,3,3-trifluoropropyl)trimethoxysilane, tridecafluorooctyltriethoxysilane, methyltrichlorosilane, dimethyldichlorosilane, trimethylchlorosilane, phenyltrichlorosilane, trimethylfluorosilane, dimethyldibromosilane, diphenyldibromosilane, hydrolyzed products of these compounds, and condensed products of the hydrolyzed products. Among these, propyltrimethoxysilane, methyltriethoxysilane, hexyltrimethoxysilane, phenyltriethoxysilane, and decyltrimethoxysilane are preferred from the standpoint of the availability.

### (2) Compound Having Two or Less Mercapto Group in Molecule

The release layer may be constituted by using a compound having two or less mercapto group in the molecule.

Examples of the compound having two or less mercapto group in the molecule include a thiol, a dithiol, a thiocarboxylic acid or a salt thereof, a dithiocarboxylic acid or a salt thereof, a thiosulfonic acid or a salt thereof, and a dithiosulfonic acid or a salt thereof, and at least one selected therefrom may be used.

The thiol is a compound having one mercapto group in the molecule, and for example, is represented by R—SH, wherein R represents an aliphatic or aromatic hydrocarbon group or a heterocyclic group, which may contain a hydroxyl group or an amino group.

The dithiol is a compound having two mercapto groups in the molecule, and for example, is represented by R(SH)₂, wherein R represents an aliphatic or aromatic hydrocarbon group or a heterocyclic group, which may contain a hydroxyl group or an amino group. The two mercapto groups may be bonded to the same carbon atom or may be bonded to different carbon atoms or nitrogen atoms.

The thiocarboxylic acid is a compound obtained by replacing a hydroxyl group of an organic carboxylic acid with a mercapto group, and for example, is represented by R—CO—SH, wherein R represents an aliphatic or aromatic hydrocarbon group or a heterocyclic group, which may contain a hydroxyl group or an amino group. The thiocarboxylic acid may be used in the form of a salt. A compound having two thiocarboxylic acid groups may also be used.

The dithiocarboxylic acid is a compound obtained by replacing two oxygen atoms in a carboxyl group of an organic carboxylic acid with sulfur atoms, and for example, is represented by R—(CS)—SH, wherein R represents an aliphatic or aromatic hydrocarbon group or a heterocyclic group, which may contain a hydroxyl group or an amino group. The dithiocarboxylic acid may be used in the form of a salt. A compound having two dithiocarboxylic acid groups may also be used.

The thiosulfonic acid is a compound obtained by replacing a hydroxyl group of an organic sulfonic acid with a mercapto group, and for example, is represented by R(SO₂)—SH, wherein R represents an aliphatic or aromatic hydrocarbon group or a heterocyclic group, which may contain a hydroxyl group or an amino group. The thiosulfonic acid may be used in the form of a salt.

The dithiosulfonic acid is a compound obtained by replacing two hydroxyl groups of an organic disulfonic acid with mercapto groups, and for example, is represented by R—((SO₂)—SH)₂, wherein R represents an aliphatic or aromatic hydrocarbon group or a heterocyclic group, which may contain a hydroxyl group or an amino group. The two thiosulfonic acid groups may be bonded to the same carbon atom or may be bonded to different carbon atoms. The dithiosulfonic acid may be used in the form of a salt.

Examples of the aliphatic hydrocarbon group that is preferred as R include an alkyl group and a cycloalkyl group, and the hydrocarbon group may contain any one or both of a hydroxyl group and an amino group.

The alkyl group is not limited, and examples thereof include a linear or branched alkyl group having from 1 to 20 carbon atoms, preferably having from 1 to 10 carbon atoms, and more preferably having from 1 to 5 carbon atoms, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having from 3 to 10 carbon atoms, and preferably having from 5 to 7 carbon atoms, such as a cyclopropyl group, a cyclobutyl group, a cyclopentyl group, a cyclohexyl group, a cycloheptyl group, and a cyclooctyl group.

Examples of the aromatic hydrocarbon group that is preferred as R include an aryl group having from 6 to 20 carbon atoms, and preferably having from 6 to 14 carbon atoms, such as a phenyl group, a phenyl group substituted with an alkyl group (e.g., a tolyl group and a xylyl group), a 1- or 2-naphthyl group, and an anthryl group, which may contain any one or both of a hydroxyl group and an amino group.

Examples of the heterocyclic group that is preferred as R include imidazole, triazole, tetrazole, benzimidazole, benzotriazole, thiazole, and benzothiazole, which may contain any one or both of a hydroxyl group and an amino group.

Preferred examples of the compound having two or less mercapto group in the molecule include 3-mercapto-1,2-propanediol, 2-mercaptoethanol, 1,2-ethanedithiol, 6-mercapto-1-hexanol, 1-octanethiol, 1-dodecanethiol, 10-hydroxy-1-dodecanethiol, 10-carboxy-1-dodecanethiol, 10-amino-1-dodecanethiol, sodium 1-dodecanethiolsulfonate, thiophenol, thiobenzoic acid, 4-aminothiophenol, p-toluenethiol, 2,4-dimethylbenzenethiol, 3-mercapto-1,2,4-triazole, and 2-mercaptobenzothiazole. Among these, 3-mercapto-1,2-propanediol is preferred from the standpoint of the water solubility and the waste processing.

### (3) Metal Alkoxide

The release layer may have a single compound or a combination of plural compounds of an aluminate compound, a titanate compound, or a zirconate compound represented by the following formula, a hydrolyzed product thereof, or a condensed product of the hydrolyzed product (hereinafter referred simply to a metal alkoxide).

(R¹)ₘ-M-(R²)ₙ

In the formula, R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; M represents any one of Al, Ti, and Zr; n represents 0, 1, or 2; and m represents an integer of 1 or more and a valence of M or less, provided that at least one of R¹ represents an alkoxy group, and m+n is a valence of M, i.e., 3 for Al, and 4 for Ti or Zr.

The metal alkoxide preferably has at least one alkoxy group. In the case where the substituents are constituted only by a hydrocarbon group selected from the group consisting of an alkyl group, a cycloalkyl group, and an aryl group, or any of the hydrocarbon groups with at least one hydrogen atom substituted with a halogen atom, with no alkoxy group present, the adhesiveness between the plate carrier and the surface of the metal foil tends to be decreased excessively. Furthermore, the metal alkoxide preferably has from 0 to 2 hydrocarbon group selected from the group consisting of an alkyl group, a cycloalkyl group, and an aryl group, or any of the hydrocarbon groups with at least one hydrogen atom substituted with a halogen atom. In the case where three or more the hydrocarbon groups are contained, the adhesiveness between the plate carrier and the surface of the metal foil tends to be decreased excessively. The alkoxy group referred in the invention includes an alkoxy group with at least one hydrogen atom substituted with a halogen atom. The metal alkoxide preferably has two or more alkoxy groups and one or two of the hydrocarbon group (including the hydrocarbon group with at least one hydrogen atom substituted with a halogen atom) for controlling the release strength between the plate carrier and the metal foil to the aforementioned range.

The alkyl group is not limited, and examples thereof include a linear or branched alkyl group having from 1 to 20 carbon atoms, preferably having from 1 to 10 carbon atoms, and more preferably having from 1 to 5 carbon atoms, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having from 3 to 10 carbon atoms, and preferably having from 5 to 7 carbon atoms, such as a cyclopropyl group, a cyclobutyl group, a cyclopentyl group, a cyclohexyl group, a cycloheptyl group, and a cyclooctyl group.

Examples of the aromatic hydrocarbon group that is preferred as R² include an aryl group having from 6 to 20 carbon atoms, and preferably having from 6 to 14 carbon atoms, such as a phenyl group, a phenyl group substituted with an alkyl group (e.g., a tolyl group and a xylyl group), a 1- or 2-naphthyl group, and an anthryl group, which may contain any one or both of a hydroxyl group and an amino group.

The hydrocarbon group may have at least one hydrogen atom that is substituted with a halogen atom, for example, substituted with a fluorine atom, a chlorine atom, or a bromine atom.

Examples of the preferred aluminate compound include trimethoxyaluminum, methyldimethoxyaluminum, ethyldimethoxyaluminum, n- or iso-propyldimethoxyaluminum, n-, iso-, or tert-butyldimethoxyaluminum, n-, iso-, or neo-pentyldimethoxyaluminum, hexyldimethoxyaluminum, octyldimethoxyaluminum, decyldimethoxyaluminum, phenyldimethoxyaluminum, an alkyl-substituted phenyldimethoxyaluminum (such as p-(methyl)phenyldimethoxyaluminum), dimethylmethoxyaluminum, triethoxyaluminum, methyldiethoxyaluminum, ethyldiethoxyaluminum, n- or iso-propyldiethoxyaluminum, n-, iso-, or tert-butyldiethoxyaluminum, pentyldiethoxyaluminum, hexyldiethoxyaluminum, octyldiethoxyaluminum, decyldiethoxyaluminum, phenyldiethoxyaluminum, an alkyl-substituted phenyldiethoxyaluminum (such as p-(methyl)phenyldiethoxyaluminum), dimethylethoxyaluminum, tri isopropoxyaluminum, methyldiisopropoxyaluminum, ethyldiisopropoxyaluminum, n- or iso-propyldiisopropoxyaluminum, n-, iso-, or tert-butyldiisopropoxyaluminum, pentyldiisopropoxyaluminum, hexyldiisopropoxyaluminum, octyldiisopropoxyaluminum, decyldiisopropoxyaluminum, phenyldiisopropoxyaluminum, an alkyl-substituted phenyldiisopropoxyaluminum (such as p-(methyl)phenyldiisopropoxyaluminum), dimethyl isopropoxyaluminum, (3,3,3-trifluoropropyl)dimethoxyaluminum, tridecafluorooctyldiethoxyaluminum, methyldichloroaluminum, dimethylchloroaluminum, phenyldichloroaluminum, dimethyl fluoroaluminum, dimethylbromoaluminum, diphenylbromoaluminum, hydrolyzed products of these compounds, and condensed products of the hydrolyzed products. Among these, trimethoxyaluminum, triethoxyaluminum, and triisopropoxyaluminum are preferred from the standpoint of the availability.

Examples of the preferred titanate compound include tetramethoxytitanium, methyltrimethoxytitanium, ethyltrimethoxytitanium, n- or iso-propyltrimethoxytitanium, n-, iso-, or tert-butyltrimethoxytitanium, n-, iso-, or neo-pentyltrimethoxytitanium, hexyltrimethoxytitanium, octyltrimethoxytitanium, decyltrimethoxytitanium, phenyltrimethoxytitanium, an alkyl-substituted phenyltrimethoxytitanium (such as p-(methyl)phenyltrimethoxytitanium), dimethyldimethoxytitanium, tetraethoxytitanium, methyltriethoxytitanium, ethyltriethoxytitanium, n- or iso-propyltriethoxytitanium, n-, iso-, or tert-butyltriethoxytitanium, pentyltriethoxytitanium, hexyltriethoxytitanium, octyltriethoxytitanium, decyltriethoxytitanium, phenyltriethoxytitanium, an alkyl-substituted phenyltriethoxytitanium (such as p-(methyl)phenyltriethoxytitanium), dimethyldiethoxytitanium, tetraisopropoxytitanium, methyltriisopropoxytitanium, ethyltriisopropoxytitanium, n- or iso-propyltriisopropoxytitanium, n-, iso-, or tert-butiyltriisopropoxytitanium, pentyltriisopropoxytitanium, hexyltriisopropoxytitanium, octyltriisopropoxytitanium, decyltriisopropoxytitanium, phenyltriisopropoxytitanium, an alkyl-substituted phenyltriisopropoxytitanium (such as p-(methyl)phenyltriisopropoxytitanium), dimethyldiisopropoxytitanium, (3,3,3-trifluoropropyl)trimethoxytitanium, tridecafluorooctyltriethoxytitanium, methyltrichlorotitanium, dimethyldichlorotitanium, trimethylchlorotitanium, phenyltrichlorotitanium, dimethyldifluorotitanium, dimethyldibromotitanium, diphenyldibromotitanium, hydrolyzed products of these compounds, and condensed products of the hydrolyzed products. Among these, tetramethoxytitanium, tetraethoxytitanium, and tetraisopropoxytitanium are preferred from the standpoint of the availability.

Examples of the preferred zirconate compound include tetramethoxyzirconium, methyltrimethoxyzirconium, ethyltrimethoxyzirconium, n- or iso-propyltrimethoxyzirconium, n-, iso-, or tert-butyltrimethoxyzirconium, n-, iso-, or neo-pentyltrimethoxyzirconium, hexyltrimethoxyzirconium, octyltrimethoxyzirconium, decyltrimethoxyzirconium, phenyltrimethoxyzirconium, an alkyl-substituted phenyltrimethoxyzirconium (such as p-(methyl)phenyltrimethoxyzirconium), dimethyldimethoxyzirconium, tetraethoxyzirconium, methyltriethoxyzirconium, ethyltriethoxyzirconium, n- or iso-propyltriethoxyzirconium, n-, iso-, or tert-butyltriethoxyzirconium, pentyltriethoxyzirconium, hexyltriethoxyzirconium, octyltriethoxyzirconium, decyltriethoxyzirconium, phenyltriethoxyzirconium, an alkyl-substituted phenyltriethoxyzirconium (such as p-(methyl)phenyltriethoxyzirconium), dimethyldiethoxyzirconium, tetraisopropoxyzirconium, methyltriisopropoxyzirconium, ethyltriisopropoxyzirconium, n- or iso-propyltriisopropoxyzirconium, n-, iso-, or tert-butyltriisopropoxyzirconium, pentyl triisopropoxyzirconium, hexyltriisopropoxyzirconium, octyltriisopropoxyzirconium, decyltriisopropoxyzirconium, phenyltriisopropoxyzirconium, an alkyl-substituted phenyltriisopropoxyzirconium (such as p-(methyl)phenyltriisopropoxyzirconium), dimethyldiisopropoxyzirconium, (3,3,3-trifluoropropyl)trimethoxyzirconium, tridecafluorooctyltriethoxyzirconium, methyltrichlorozirconium, dimethyldichlorozirconium, trimethylchlorozirconium, phenyltrichlorozirconium, dimethyldifluorozirconium, dimethyldibromozirconium, diphenyldibromozirconium, hydrolyzed products of these compounds, and condensed products of the hydrolyzed products. Among these, tetramethoxyzirconium, tetraethoxyzirconium, and tetraisopropoxyzirconium are preferred from the standpoint of the availability.

### (4) Release Layer Formed of Resin Coated Film

The plate carrier and the metal foil may be adhered by using a resin coated film constituted by one or plural resins selected from a silicone, an epoxy resin, a melamine resin, and a fluorine resin, and thereby the adhesiveness can be appropriately lowered to make the release strength controlled to the range described later.

The control of the release strength for achieving such adhesiveness may be performed by using a resin coated film constituted by one or plural resins selected from a silicone, an epoxy resin, a melamine resin, and a fluorine resin as described later. The resin film may be subjected to a baking treatment under a prescribed condition described later, and used between the plate carrier and the metal foil, which are then adhered by hot pressing, and thereby the adhesiveness can be appropriately lowered to make the release strength controlled to the aforementioned range.

Examples of the epoxy resin include a bisphenol A type epoxy resin, a bisphenol F type epoxy resin, a novolak type epoxy resin, a brominated epoxy resin, an amine type epoxy resin, a flexible epoxy resin, a hydrogenated bisphenol A type epoxy resin, a phenoxy resin, and a brominated phenoxy resin.

Examples of the melamine resin include a methyl etherified melamine resin, a butylated urea melamine resin, a butylated melamine resin, a methylated melamine resin, and a butyl alcohol-modified melamine resin. The melamine resin may be a mixed resin of the aforementioned resin with a butylated urea resin, a butylated benzoguanamine resin, or the like.

The epoxy resin preferably has a number average molecular weight of from 2,000 to 3,000, and the melamine resin preferably has a number average molecular weight of from 500 to 1,000. When the resin has the number average molecular weight, the resin can be formed into a coating composition, and the adhesion strength of the resin coated film can be easily controlled to the prescribed range.

Examples of the fluorine resin include polytetrafluoroethylene, polychlorotrifluoroethylene, polyvinylidene fluoride, and polyvinyl fluoride.

Examples of the silicone include methylphenylpolysiloxane, methylhydropolysiloxane, dimethylpolysiloxane, modified dimethylpolysiloxane, and mixtures thereof. Examples of the modification herein include epoxy modification, alkyl modification, amino modification, carboxyl modification, alcohol modification, fluorine modification, alkyl aralkyl polyether modification, epoxy polyether modification, polyether modification, alkyl higher alcohol ester modification, polyester modification, acyloxyalkyl modification, halogenated alkylacyloxyalkyl modification, halogenated alkyl modification, aminoglycol modification, mercapto modification, and hydroxyl group-containing polyester modification.

When the thickness of the resin coated film is too small, the resin coated film may be difficult to form due to the small thickness thereof, which tends to deteriorate the productivity. When the thickness of the film exceeds a certain value, there may be no further enhancement of the release property of the resin coated film, but the production cost of the resin coated film tends to increase. In this point of view, the thickness of the resin coated film is preferably from 0.1 to 10 μm, and more preferably from 0.5 to 5 μm. The thickness of the resin coated film can be achieved by coating the resin coating composition at a prescribed coating amount in the procedure described later.

In the resin coated film, the silicone functions as a release agent. When the total amount of the epoxy resin and the melamine resin is too large with respect to the amount of the silicone, the release strength that is imparted by the resin coated film to between the plate carrier and the metal foil may be increased, and thereby there may be the case where the metal foil with a carrier is difficult to be released by the hand due to the decreased release property of the resin coated film. When the total amount of the epoxy resin and the melamine resin is too small, on the other hand, the release strength may be decreased, and thereby there may be the case where the metal foil with a carrier is released in the transportation or processing thereof. In this point of view, the epoxy resin and the melamine resin are preferably contained in a total amount of from 10 to 1,500 parts by mass, and more preferably from 20 to 800 parts by mass, per 100 parts by mass of the silicone.

The fluorine resin functions as a release agent as similar to the silicone, and has an effect of the enhancement of the heat resistance of the resin coated film. When the amount of the fluorine resin is too large with respect to the silicone, there may be the case where the metal foil with a carrier is released in the transportation or processing of the laminated material, and also the temperature that is necessary for the baking step described later may be increased, which is economically disadvantageous. In this point of view, the amount of the fluorine resin is preferably from 0 to 50 parts by mass, and more preferably from 0 to 40 parts by mass, per 100 parts by mass of the silicone.

The resin coated film may contain one or more kinds of surface roughening particles selected from SiO₂, MgO, Al₂O₃, BaSO₄, and Mg(OH)₂, in addition to the silicone, the epoxy resin and/or the melamine resin, and depending on necessity the fluorine resin. The surface roughening particles contained in the resin coated film impart unevenness to the surface of the resin coated film. The unevenness imparts unevenness to the surface of the plate carrier or the metal foil, on which the resin coated film is coated, so as to provide a matte surface. The content of the surface roughening particles is not particularly limited as far as the resin coated film has unevenness, and is preferably from 1 to 10 parts by mass per 100 parts by mass of the silicone.

The surface roughening particles preferably have a particle diameter of from 15 nm to 4 μm. The particle diameter herein means the average particle diameter (i.e., the average value of the maximum particle diameter and the minimum particle diameter) measured from a micrograph of a scanning electron microscope (SEM), or the like. When the particle diameter of the surface roughening particles is in the range, the extent of the unevenness on the surface of the resin coated film can be easily controlled, and consequently the extent of the unevenness on the surface of the plate carrier or the metal foil can be easily controlled. Specifically, the extent of the unevenness on the surface of the plate carrier or the metal foil may be approximately 4.0 μm in terms of maximum height roughness Ry determined in JIS.

The method for producing the laminated material will be described.

The metal foil with a carrier can be obtained through a procedure containing a step of coating the aforementioned resin coated film on a surface of at least one of a plate carrier and a metal foil, and a baking step of curing the coated resin coated film. The steps will be described below.

### (Coating Step)

The coating step is a step of coating a resin coating composition containing silicone as a base material, an epoxy resin and a melamine resin as a curing agent, and depending on necessity a fluorine resin as a release agent, on one surface or both surfaces of a plate carrier, so as to forma resin coated film. The resin coating composition may be obtained by dissolving the epoxy resin, the melamine resin, the fluorine resin, and the silicone in an organic solvent, such as an alcohol. The mixing amount (addition amount) in the resin coating composition is preferably from 10 to 1,500 parts by mass for the total amount of the epoxy resin and the melamine resin per 100 parts by mass of the silicone. The amount of the fluorine resin is preferably from 0 to 50 parts by mass per 100 parts by mass of the silicone.

The coating method in the coating step is not particularly limited, and may be a gravure coating method, a bar coating method, a roll coating method, a curtain flow coating method, a method using an electrostatic coating machine, and the like, and a gravure coating method is preferred from the standpoint of the uniformity of the resin coated film, and the convenience of operation. The coating amount is preferably from 1.0 to 2.0 g/m² in terms of amount of the resin for providing the preferred thickness of the resin coated film 3, i.e., from 0.5 to 5 μm.

In the gravure coating method, the resin coating composition filled in depressed portions (cells) provided on a surface of a roll is transferred to the plate carrier, thereby forming the resin coated film on the surface of the plate carrier. Specifically, a lower roll having cells provided on the surface thereof is immersed in a resin coating composition, and the resin coating composition is drawn into the cells through rotation of the lower roll. The plate carrier is disposed between the lower roll and an upper roll provided above the lower roll, and the lower roll and the upper roll are rotated while the plate carrier is pressed with the upper roll onto the lower roll, whereby the plate carrier is conveyed, and simultaneously the resin coating composition having been drawn into the cells is transferred (coated) on one surface of the plate carrier.

A doctor blade is disposed on the side where the plate carrier is conveyed in, so as to be contact with the surface of the lower roll, whereby the excessive resin coating composition having been drawn on to the surface of the roll except for the cells is removed, and the prescribed amount of the resin coating composition is coated on the surface of the plate carrier. In the case where the count of the cells (i.e., the size and the depth) is large, or in the case where the viscosity of the resin coating composition is large, the resin coated film formed on one surface of the plate carrier may not be smooth. Accordingly, a smoothing roll may be disposed on the side where the plate carrier is conveyed out, so as to retain the smoothness degree of the resin coated film.

In the case where the resin coated films are formed on both surfaces of the plate carrier, after forming the resin coated film on one surface of the plate carrier, and then the plate carrier is turned upside down, and then again disposed between the lower roll and upper roll. The resin coating composition in the cells of the lower roll is then transferred (coated) on the back surface of the plate carrier in the similar manner as above.

### (Baking Step)

In the baking step, the resin coated film formed in the coating step is subjected to a baking treatment at from 125 to 320° C. (baking temperature) for from 0.5 to 60 seconds (baking time). By subjecting the resin coated film formed of the resin coating composition having the prescribed mixing amounts to the baking treatment under the prescribed conditions, the release strength between the plate carrier and the metal foil imparted by the resin coated film can be controlled to the prescribed range. In the invention, the baking temperature is the achieving temperature of the plate carrier. The heating measure used in the baking treatment may be a known device.

Under the condition that makes the baking insufficient, for example, a baking temperature of less than 125° C. or a baking time of less than 0.5 second, the resin coated film may be insufficiently cured to provide the release strength exceeding 200 gf/cm, and thus the release property may be lowered. Under the condition that makes the baking excessive, for example a baking temperature exceeding 320° C., the resin coated film may be deteriorated to provide the release strength exceeding 200 gf/cm, and thus the workability on releasing may be deteriorated. There may also be a case where the plate carrier is deteriorated due to the high temperature. In the case where the baking time exceeds 60 seconds, the productivity may be deteriorated.

In the method for producing a laminated material, the resin coating composition in the coating step may contain the silicone as a base material, the epoxy resin and the melamine resin as a curing agent, the fluorine resin as a release agent, and one or more kinds of the surface roughening particles selected from SiO₂, MgO, Al₂O₃, BaSO₄, and Mg(OH)₂.

Specifically, the resin coating composition may be the aforementioned silicone-containing resin solution having the surface roughening particles further added thereto. The addition of the surface roughening particles to the resin coating composition may provide unevenness on the surface of the resin coated film, and the unevenness imparts unevenness to the plate carrier or the metal foil, so as to provide a matte surface. For providing the plate carrier or the metal foil having the matte surface, the mixing amount (addition amount) of the surface roughening particles in the resin coating composition is preferably from 1 to 10 parts by mass per 100 parts by mass of the silicone. It is more preferred that the surface roughening particles have a particle diameter of from 15 nm to 4 μm.

The production method of the invention has been as described above, and in the working of the invention, other steps may be provided among the aforementioned steps or before or after the steps in such a range that does not adversely affect the steps. For example, a rinsing step of rinsing the surface of the plate carrier may be performed before the coating step.

Resin Capable of being Laminated on Copper Foil with Release Layer on Side of Release Layer (Insulating Substrate 1 Described Later)

The resin that is capable of being laminated on the copper foil with a release layer on the side of the release layer may be a known resin. A known resin that is used as the plate carrier may also be used. The resin may be the resin layer described later. The resin that is capable of being laminated on the copper foil with a release layer on the side of the release layer is not particularly limited, may be a phenol resin, a polyimide resin, an epoxy resin, natural rubber, a pine resin, or the like, and a thermosetting resin is preferred. A prepreg may also be used therefor. The prepreg before adhering to the copper foil is preferably in a B stage. The prepreg (C stage) has a linear expansion coefficient of from 12 to 18 (×10⁻⁶/° C.), which is approximately equal to that of the copper foil as the constitutional material of the substrate, i.e., 16.5 (×10⁻⁶/° C.), or that of a stainless steel pressed sheet, i.e., 17.3 (×10⁻⁶/° C.), and thus is advantageous since it can prevent the positional displacement of circuits due to the phenomenon that the substrate sizes before and after pressing are different from the designed size (i.e., the change in scaling). Furthermore, as the synergistic effect of the advantages, a multilayer ultrathin core-less substrate can be produced. The prepreg used herein may be the same as or different from the prepreg constituting the circuit board.

The prepreg preferably has a high glass transition temperature Tg from the standpoint of retaining the release strength after heating to the optimum range, and for example, the glass transition temperature Tg may be from 120 to 320° C., and preferably from 170 to 240° C. The glass transition temperature Tg is a value that is measured with DSC (differential scanning calorimetry).

The thermal expansion ratio of the resin is preferably in a range of from +10% to −30% of the thermal expansion ratio of the copper foil. With the thermal expansion ratio within the range, the positional displacement of circuits due to the difference in thermal expansion between the copper foil and the resin can be effectively prevented, and thereby the formation of defective products can be reduced to enhance the yield.

The thickness of the resin is not particularly limited, and may be rigid or flexible, and a too large thickness may adversely affect the heat distribution during the hot press, whereas a too small thickness may cause deflection of the printed wiring board to prevent the board from flowing in the production process. The thickness is thus generally 5 μm or more and 1,000 μm or less, preferably 50 μm or more and 900 μm or less, and more preferably 100 μm or more and 400 μm or less.

### <Laminated Material>

A laminated material (such as a copper-clad laminated material) can be produced by using the copper foil with a release layer of the invention.

The laminated material using the copper foil with a release layer of the invention may have, for example, a structure obtained by laminating “release layer/barrier layer/copper foil/resin or prepreg” in this order.

The resin or prepreg may be the resin layer described later, and may contain a resin, a resin curing agent, a compound, a curing accelerator, a dielectric material, a reaction catalyst, a crosslinking agent, a polymer, a prepreg, an aggregate, and the like used for the resin layer described later. The copper foil with a release layer may be smaller than the resin or prepreg in planar view.

### <Roughening Treatment and Other Surface Treatments>

On the copper foil surface of the copper foil with a release layer, a roughening treatment layer may be provided by performing a roughening treatment, for example, for the enhancement of the adhesiveness to the insulating substrate or the resin. The roughening treatment may be performed, for example, by forming roughening particles with copper or a copper alloy. The roughening treatment may be a fine roughening treatment. The roughening treatment layer may be a layer formed of a single material selected from the group consisting of copper, nickel, phosphorus, tungsten, arsenic, molybdenum, chromium, titanium, iron, vanadium, cobalt, and zinc, or an alloy containing one or more thereof, or the like. The roughening particles may be formed with copper or a copper alloy, and then a roughening treatment for forming secondary particles or tertiary particles may be further performed with a single material or an alloy of nickel, cobalt, copper, or zinc. Thereafter, a heat resistant layer or a rust preventing layer may be formed with a single material and/or an alloy and/or an oxide and/or a nitride and/or a silicide and/or the like of nickel, cobalt, copper, zinc, tin, molybdenum, tungsten, phosphorus, arsenic, chromium, vanadium, titanium, aluminum, gold, silver, a platinum group element, iron, or tantalum, and further thereon, such treatments as a chromate treatment and a silane coupling treatment may be performed. Without the roughening treatment performed, a heat resistant layer or a rust preventing layer may be formed with a single material and/or an alloy and/or an oxide and/or a nitride and/or a silicide and/or the like of nickel, cobalt, copper, zinc, tin, molybdenum, tungsten, phosphorus, arsenic, chromium, vanadium, titanium, aluminum, gold, silver, a platinum group element, iron, or tantalum, and further thereon, such treatments as a chromate treatment and a silane coupling treatment may be performed. That is, one or more layer selected from the group consisting of a heat resistant layer, a rust preventing layer, a chromate treatment layer, and a silane coupling treatment layer may be formed on the roughening treatment layer, and one or more layer selected from the group consisting of a heat resistant layer, a rust preventing layer, a chromate treatment layer, and a silane coupling treatment layer may be formed on the copper foil surface of the copper foil with a release layer or on the surface of the ultrathin copper layer of the copper foil with a carrier. The heat resistant layer, the rust preventing layer, the chromate treatment layer, and the silane coupling treatment layer each may be formed of plural layers (for example, two or more layers, or three or more layers).

For example, copper-cobalt-nickel alloy plating as the roughening treatment may be performed to form a ternary alloy layer containing copper in a deposition amount of from 15 to 40 mg/dm², cobalt in a deposition amount of from 100 to 3,000 μg/dm², and nickel in a deposition amount of from 100 to 1,500 μg/dm² by electroplating. When the deposition amount of Co is less than 100 μg/dm², the heat resistance may be deteriorated, and the etching property may be deteriorated. The deposition amount of Co that exceeds 3,000 μg/dm² is not preferred in the case where the influence of magnetism is necessarily considered, and in this case, etching discoloration may occur, and the acid resistance and the chemical resistance may be deteriorated. When the deposition amount of Ni is less than 100 μg/dm², the heat resistance may be deteriorated. When the deposition amount of Ni exceeds 1,500 μg/dm², the etching residue may be increased. The preferred deposition amount of Co is from 1,000 to 2,500 μg/dm², and the preferred deposition amount of Ni is from 500 to 1,200 μg/dm². The etching discoloration herein means that in the case where the etching is performed with copper chloride, Co remains undissolved, and the etching residue herein means that in the case where alkali etching is performed with ammonium chloride, Ni remains undissolved.

An example of the general plating bath and the general plating condition for forming the copper-cobalt-nickel ternary alloy plating is as follows.

Plating bath composition: Cu: 10 to 20 g/L, Co: 1 to 10 g/L, Ni: 1 to 10 g/L

pH: 1 to 4

Temperature: 30 to 50° C.

Current density Dₖ: 20 to 30 A/dm²

Plating time: 1 to 5 seconds

The chromate treatment layer means a layer that is treated with a solution containing chromic anhydride, chromic acid, dichromic acid, a chromate salt, or a dichromate salt. The chromate treatment layer may contain an element, such as Co, Fe, Ni, Mo, Zn, Ta, Cu, Al, P, W, Sn, As, and Ti (which may be in any form of a metal, an alloy, an oxide, a nitride, a sulfide, and the like). Specific examples of the chromate treatment layer include a chromate treatment layer that is treated with a chromic anhydride or potassium dichromate aqueous solution, and a chromate treatment layer that is treated with a treatment solution containing chromic anhydride or potassium dichromate and zinc.

The silane coupling treatment layer may be formed by using a known silane coupling agent, and may be formed by using a silane coupling agent or the like, such as an epoxy silane, an amino silane, a methacryloxy silane, a mercapto silane, a vinyl silane, an imidazole silane, and a triazine silane. The silane coupling agents may be used as a mixture of two or more kinds thereof. Among these, the silane coupling treatment layer is preferably formed by using an amino silane coupling agent or an epoxy silane coupling agent.

On the copper foil surface or the release layer surface of the copper foil with a release layer, or on the surface of the roughening treatment layer, the heat resistant layer, the rust preventing layer, the silane coupling treatment layer, or the chromate treatment layer, the surface treatments described in WO 2008/053878, JP-A-2008-111169, Japanese Patent No. 5024930, WO 2006/028207, Japanese Patent No. 4828427, WO 2006/134868, Japanese Patent No. 5046927, WO 2007/105635, Japanese Patent No. 5180815, and JP-A-2013-19056 may be performed.

The roughening treatment layer may be provided on the copper foil surface of the copper foil with a release layer, and one or more layer selected from the group consisting of the heat resistant layer, the rust preventing layer, the chromate treatment layer, and the silane coupling treatment layer may be provided on the roughening treatment layer.

The roughening treatment layer may be provided on the copper foil surface of the copper foil with a release layer; the heat resistant layer and the rust preventing layer may be provided on the roughening treatment layer; the chromate treatment layer may be provided on the heat resistant layer and the rust preventing layer; and the silane coupling layer may be provided on the chromate treatment layer.

A resin layer may be provided on the copper foil surface, the release layer surface of the copper foil with a release layer, or the roughening treatment layer, or on the heat resistant layer, the rust preventing layer, the chromate treatment layer, or the silane coupling treatment layer. The resin layer may be an insulating resin layer.

The resin layer may be an adhesive, and may be an insulating resin layer for adhesion in a semi-cured state (B stage). The semi-cured state (B stage) may include such a state that the insulating resin layer provides no tacky feeling on touching the surface thereof with the fingers, and the insulating resin layers can be stacked and stored, but undergo the curing reaction by further subjecting to a heat treatment.

The resin layer may contain a thermosetting resin, and may be a thermoplastic resin. The resin layer may contain a thermoplastic resin. The kinds of the resins are not particularly limited, and preferred examples of the resin layer include layers containing one or more resins selected from the group consisting of an epoxy resin, a polyimide resin, a polyfunctional cyanate ester compound, a maleimide compound, a polyvinylacetal resin, a urethane resin, a polyether sulfone, a polyether sulfone resin, an aromatic polyamide resin, an aromatic polyamide resin polymer, a rubber-like resin, a polyamine, an aromatic polyamine, a polyamideimide resin, a rubber-modified epoxy resin, a phenoxy resin, a carboxyl group-modified acrylonitrile-butadiene resin, a polyphenylene oxide, a bismaleimide-triazine resin, a thermosetting polyphenylene oxide resin, a cyanate ester resin, a carboxylic anhydride, a polybasic carboxylic anhydride, a linear polymer having a crosslinkable functional group, a polyphenylene ether resin, 2,2-bis(4-cyanatophenyl)propane, a phosphorus-containing phenol compound, manganese naphthenate, 2,2-bis(4-glycidylphenyl)propane, a polyphenylene ether-cyanate resin, a siloxane-modified polyamideimide resin, a phosphazene resin, a rubber-modified polyamideimide resin, isoprene, a hydrogenated polybutadiene, a polyvinyl butyral, phenoxy, an epoxy polymer, a aromatic polyamide, a fluorine resin, a bisphenol, a block copolymer polyimide resin, and a cyanoester resin.

The epoxy resin has two or more epoxy groups in the molecule thereof, and any one that can be applied to the purposes of an electric or electronic material can be used without problem. The epoxy resin is preferably an epoxy resin obtained by epoxidizing with a compound having two or more glycidyl groups in the molecule thereof. The epoxy resin may be used as one kind or as a mixture of two or more kinds selected from the group consisting of a bisphenol A type epoxy resin, a bisphenol F type epoxy resin, a bisphenol S type epoxy resin, a bisphenol AD type epoxy resin, a novolak type epoxy resin, a cresol novolak type epoxy resin, an alicyclic epoxy resin, a brominated epoxy resin, a phenol novolak type epoxy resin, a naphthalene type epoxy resin, a brominated bisphenol A type epoxy resin, an o-cresol novolak type epoxy resin, a rubber-modified bisphenol A type epoxy resin, a glycidylamine type epoxy resin, triglycidyl isocyanurate, a glycidylamine compound, such as N,N-diglycidylaniline, a glycidyl ester compound, such as glycidyl tetrahydrophthalate ester, a phosphorus-containing epoxy resin, a biphenyl type epoxy resin, a biphenyl novolak type epoxy resin, a trishydroxyphenylmethane type epoxy resin, and a tetraphenylethane type epoxy resin, and hydrogenated products and halogenated products of these epoxy resins may also be used.

The phosphorus-containing epoxy resin used may be a known epoxy resin that contains phosphorus. The phosphorus-containing epoxy resin is preferably, for example, an epoxy resin that is obtained as a derivative from 9,10-dihydro-9-oxa-10-phosphaphenanthrene-10-oxide having two or more epoxy groups in the molecule thereof.

The resin layer may contain a resin, a resin curing agent, a compound, a curing accelerator, a dielectric material (which may be any dielectric material, such as a dielectric material containing an inorganic compound and/or an organic compound, and a dielectric material containing a metal oxide), a reaction catalyst, a crosslinking agent, a polymer, a prepreg, an aggregate, and the like that have been known. The resin layer may contain, for example, the substances (such as the resin, the resin curing agent, the compound, the curing accelerator, the dielectric material, the reaction catalyst, the crosslinking agent, the polymer, the prepreg, and the aggregate) described in WO 2008/004399, WO 2008/053878, WO 2009/084533, JP-A-11-5828, JP-A-11-140281, Japanese Patent No. 3184485, WO 97/02728, Japanese Patent No. 3676375, JP-A-2000-43188, Japanese Patent No. 3612594, JP-A-2002-179772, JP-A-2002-359444, JP-A-2003-304068, Japanese Patent No. 3992225, JP-A-2003-249739, Japanese Patent No. 4136509, JP-A-2004-82687, Japanese Patent No. 4025177, JP-A-2004-349654, Japanese Patent No. 4286060, JP-A-2005-262506, Japanese Patent No. 4570070, JP-A-2005-53218, Japanese Patent No. 3949676, Japanese Patent No. 4178415, WO 2004/005588, JP-A-2006-257153, JP-A-2007-326923, JP-A-2008-111169, Japanese Patent No. 5024930, WO 2006/028207, Japanese Patent No. 4828427, JP-A-2009-67029, WO 2006/134868, Japanese Patent No. 5046927, JP-A-2009-173017, WO 2007/105635, Japanese Patent No. 5180815, WO 2008/114858, WO 2009/008471, JP-A-2011-14727, WO 2009/001850, WO 2009/145179, WO 2011/068157, and JP-A-2013-19056, and/or may be formed by the formation method of the resin layer or the formation device therefor described in these literatures.

The resin may be dissolved in a solvent, such as methyl ethyl ketone (MEK) or toluene, to form a resin solution, which is then coated on the copper foil or the release layer of the copper foil with a release layer, or on the heat resistant layer, the rust preventing layer, the chromate treatment layer, or the silane coupling treatment layer, for example, by a roll coater method, and then depending on necessity, the solvent is removed by drying under heating to make a B stage state. The drying may be performed, for example, by using a hot air drying furnace, and the drying temperature may be from 100 to 250° C., and preferably from 130 to 200° C.

The copper foil with a release layer having the resin layer (i.e., the copper foil with a release layer having the resin) may be used in such an embodiment that the resin layer is superimposed to a substrate, the resin layer is heat cured by subjecting the assembly to heat press, the carrier is released to expose the ultrathin copper layer (what is exposed is naturally the surface of the ultrathin copper layer on the side of the release layer), and then a prescribed wiring pattern is formed thereon.

The use of the copper foil with a release layer having the resin layer can reduce the number of sheets of the prepreg material used in the production of a multilayer printed wiring board. Furthermore, the thickness of the resin layer can be such a thickness that can ensure the interlayer insulation, and a copper-clad laminated board can be produced with completely no prepreg material used. At this time, the smoothness of the surface can also be further improved by undercoating an insulating resin on the surface of the substrate.

In the case where no prepreg material is used, the material cost of the prepreg material can be saved, and the lamination process can be simplified, which may provide an economical advantage. Furthermore, the thickness of the multilayer printed wiring board thus produced can be reduced to the extent corresponding to the thickness of the prepreg material, which may provide an advantage that an ultrathin multilayer printed wiring board having a thickness per one layer of 100 μm or less can be produced.

The thickness of the resin layer is preferably from 0.1 to 80 μm. When the thickness of the resin layer is less than 0.1 μm, the adhesion force may be decreased, and when the copper foil with a carrier having the resin is laminated on a substrate having an inner layer material without a prepreg material intervening between them, the interlayer insulation between the inner layer material and the circuit cannot be ensured in some cases.

When the thickness of the resin layer is larger than 80 μm, on the other hand, it may be difficult to form the resin layer having the target thickness by one time operation in the coating step, which may be economically disadvantageous due to the unnecessarily increased material cost and man-hours. Furthermore, the resin layer thus formed may have poor flexibility, which may facilitate the formation of cracks or the like in handling, and the smooth lamination operation may be difficult in some cases due to the excessive flow of the resin in the press adhesion under heat to the inner layer material.

As another embodiment of the product of the copper foil with a release layer having the resin, a copper foil having the resin can be produced in such a manner that the resin layer is coated on the copper foil or the release layer of the copper foil with a release layer, or on the heat resistant layer, the rust preventing layer, the chromate treatment layer, or the silane coupling treatment layer, and the resin layer is made into a semi-cured state.

Furthermore, electronic components may be mounted on the printed wiring board to complete a printed circuit board. In the invention, the “printed wiring board” thus encompasses a printed wiring board having electronic components mounted thereon, a printed circuit board, and a printed board.

An electronic apparatus may be produced by using the printed wiring board, an electronic apparatus may be produced by using the printed circuit board having electronic components mounted thereon, and an electronic apparatus may be produced by using the printed board having electronic components mounted thereon. Some examples of the production process of a printed wiring board using the copper foil with a release layer according to the invention will be shown below.

In one embodiment of the production method of a printed wiring board according to the invention, an embedded circuit may be formed by the subtractive method. In the invention, the subtractive method means such a method that the unnecessary part of the copper foil on the copper-clad laminated board is selectively removed by etching or the like, so as to form a conductor pattern. An example of the production method of a printed circuit board containing a step of forming an embedded circuit by the subtractive method using the copper foil with a release layer of the invention will be described below. In the description herein, the “circuit” may include wiring.

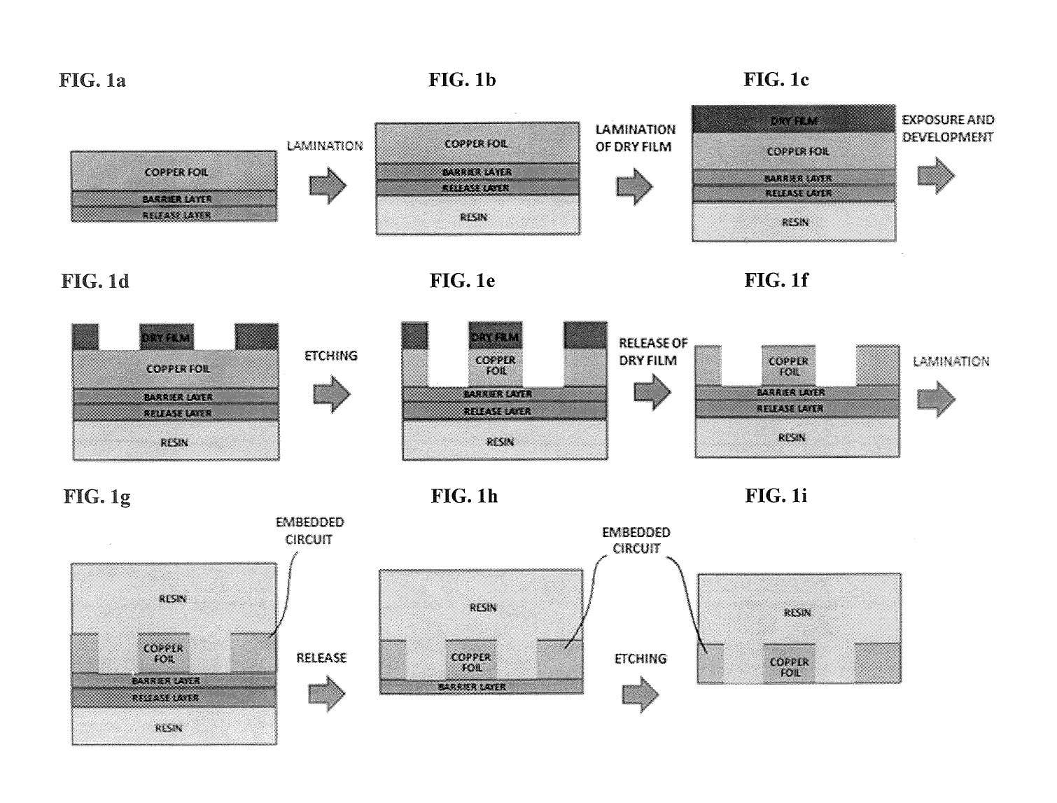

FIGS. 1a-1i comprise a schematic illustration showing the method for forming an embedded circuit by using the copper foil with a release layer according to one embodiment of the invention. In the method for forming an embedded circuit by using the copper foil with a release layer according to one embodiment of the invention, on the copper foil with a release layer of the invention (FIG. 1a), an insulating substrate 1 is laminated on the side of the release layer thereof (FIG. 1b). Then, a dry film (DF) is laminated on the copper foil with a release layer having the insulating substrate 1 laminated thereon, on the side of the copper foil (FIG. 1c). Then, the dry film is patterned through exposure and development (FIG. 1d), and then the copper foil is etched to form a circuit (FIG. 1e). Then, the dry film is released to expose the circuit (FIG. 1f). Then, the exposed circuit is covered with an insulating substrate 2 to embed the circuit (FIG. 1g). Then, the insulating substrate 1 is released from the laminated material of the circuit embedded in the insulating substrate 2 and the barrier layer through the release layer, so as to expose the barrier layer (FIG. 1h). Then, the barrier layer is removed by etching to expose the circuit embedded in the insulating substrate 2 (FIG. 1i). The embedded circuit can be thus obtained in this manner, and the printed wiring board using the embedded circuit can be produced.

In the case where the copper foil is partially removed as in FIG. 1e and the like, the copper foil is preferably removed by a method that can remove the copper foil but is difficult to remove the barrier layer in contact with the copper foil. For example, the copper foil is more preferably removed by using an etching solution that dissolves the copper foil but is difficult to dissolve the barrier layer. The etching solution used may be a selective etching solution. The barrier layer has dissolution resistance to a copper etchant or a copper etching solution, and thus a known copper etchant or a known copper etching solution may be used as the etchant or the etching solution for removing the copper foil.

In the case where the barrier layer is removed as in FIG. 1i and the like, the barrier layer is preferably removed by a method that can remove the barrier layer but is difficult to remove the circuit in contact with the barrier layer. For example, in the case where the circuit is copper, the barrier layer is preferably removed by using an etching solution that dissolves the barrier layer but is difficult to dissolve the circuit which is copper.

The etching solution used may be a selective etching solution. The selective etching solution used may be any type of selective etching solutions. The selective etching solution used may be a known selective etching solution.

Examples of the selective etching solution include the following etching solutions.

Nickel selective etching solution NC and nickel etching solution H, produced by Nihon Kagaku Sangyo Co., Ltd.
Element dissolving: Ni
Element difficult to dissolve: Ti, Au, Al, Cr, Cu, Ag, etc.

Flicker MH, produced by Nihon Kagaku Sangyo Co., Ltd., and MEC Remover CH Series, produced by MEC Co., Ltd.
Element dissolving: Ni—Cr alloy
Element or alloy difficult to dissolve: Cu MEC Remover NH-1860 Series, produced by MEC Co., Ltd.
Element dissolving: Ni
Element or alloy difficult to dissolve: Cu MEC Albrite AS-1250, produced by MEC Co., Ltd.
Element dissolving: Al
Element or alloy difficult to dissolve: Cu Selective Etching Solution, produced by MEC Co., Ltd.
Element dissolving: Co
Element or alloy difficult to dissolve: Cu

Copper selective etching solution CS, produced by Nihon Kagaku Sangyo Co., Ltd.
Element dissolving: Cu
Element or alloy difficult to dissolve: Ti, Cr, Sn, W, Au, Ni—Cr alloy, stainless steel, etc.

Copper selective etching solution CSD, produced by Nihon Kagaku Sangyo Co., Ltd.
Element dissolving: Cu
Element or alloy difficult to dissolve: Ti, Cr, W, Au, Ni—Cr alloy, stainless steel, Ag, Mo, etc.

Copper selective etching solution CSS, produced by Nihon Kagaku Sangyo Co., Ltd.
Element dissolving: Cu
Element or alloy difficult to dissolve: Ti, Cr, W, Au, Ni—Cr alloy, stainless steel, Ni, Sn, Ag, Mo, etc.

Mecbrite SF-5420, produced by MEC Co., Ltd.
Element dissolving: Cu
Element or alloy difficult to dissolve: Ni Selective Etching Solution, produced by MEC Co., Ltd.
Element dissolving: Cu
Element or alloy difficult to dissolve: Co, Sn, Al, Mo, In, Bi, Ni—Cr alloy, and ITO (indium tin oxide)

Selective Etching Solution Mecremover S-651A, produced by MEC Co., Ltd.
Element dissolving: Sn, Ag, Zn, Al, Ti, Bi, Cr, Fe, Co, Ni, Pd, Au, and Pt
Element or alloy difficult to dissolve: Cu and Cu alloy

Aqueous solution containing inorganic acid, such as nitric acid
Element dissolving: Sn, Ag, Zn, Al, Ti, Bi, Cr, Fe, Co, Ni, Pd, Au, and Pt
Element or alloy difficult to dissolve: Cu and Cu alloy

Acidic aqueous solution containing thiocarbonyl compound and halogenide ion
Element or oxide dissolving: oxides containing one or more element selected from the group consisting of Zn, Sn, Al, In and Ga
Element or alloy difficult to dissolve: Cu and Cu alloy

For example, thiocarbonyl compounds described in JP 2013-135039 A can be used as the thiocarbonyl compound.

Aqueous solution containing oxidizing metal ion source, one or more acid selected from the group consisting of inorganic acids and organic acids, and azole having only nitrogen atom as hetero atom of heterocyclic ring
Element or alloy dissolving: Cu and Cu alloy
Element or oxide difficult to dissolve: oxides containing one or more element selected from the group consisting of Zn, Sn, Al, In, and Ga

Alkaline chromium etching solution, produced by Nihon Kagaku Sangyo Co., Ltd.
Element dissolving: Cr and Cr alloy
Element or alloy difficult to dissolve: Cu, Ni, Au, Ti, Co., Si, etc.

The selective etching solution used may be the etching solutions, the acids, the aqueous solutions, and the other solutions described in JP-A-2013-135039 and JP-A-2005-23301.

The insulating substrates 1 and 2 used each may be an embedding resin. The embedding resin used may be a known resin and a known prepreg. For example, a BT (bismaleimide triazine) resin, a prepreg containing a glass cloth impregnated with a BT resin, and ABF Film and ABF, produced by Ajinomoto Fine-Techno Co., Inc. may be used. The insulating substrates 1 and 2 used and the embedding resin each used may be a known resin, or the resin layer and/or the resin and/or the prepreg described in the description herein.

The method for producing a printed wiring board of the invention may be a method for producing a printed wiring board, containing a step of laminating a resin substrate on the surface on the side of the release layer of the copper foil with a release layer of the invention; a step of forming a circuit on a portion of the copper foil of the copper foil with a release layer having the resin substrate laminated thereon, embedding the circuit with a resin, and then forming two layers of a circuit and a resin layer at least once on the resin; and a step of, after forming the two layers of the resin layer and the circuit, releasing the copper foil with a release layer from the resin substrate (core-less process). The method for producing a printed circuit board may further contain thereafter a step of removing the release layer and the barrier layer from the released copper foil with a release layer (core-less process).

The method for producing a printed wiring board of the invention may be a method for producing a printed wiring board, containing a step of laminating a resin substrate on the surface on the side of the copper layer or the surface on the side of the release layer of the copper foil with a release layer of the invention; a step of forming two layers of a resin layer and a circuit at least once on the surface of the copper foil laminated on the resin substrate or the surface of the copper foil with a release layer opposite to the surface of the release layer; and a step of, after forming the two layers of the resin layer and the circuit, releasing the two layers of the resin layer and the circuit from the copper foil with a release layer (core-less process). The two layers of the resin layer and the circuit may be provided in the order of the resin layer and the circuit, and may be provided in the order of the circuit and the resin layer. As a specific example of the core-less process, a resin substrate is laminated on the surface on the side of the copper foil or the surface on the side of the release layer of the copper foil with a release layer of the invention, so as to produce a laminated material (which may be referred to as a copper-clad laminated board or a copper-clad laminated material). Thereafter, a resin layer is formed on the surface on the side of the copper foil laminated on the resin substrate or the surface of the copper foil with a release layer opposite to the surface on the side of the release layer. On the resin layer formed on the surface on the side of the release layer or the surface on the side of the copper foil, another one of the copper foil with a release layer may be laminated on the side of the release layer or the side of the copper foil. A laminated material containing structures each containing release layer/barrier layer/copper layer laminated in this order or copper foil/barrier layer/release layer laminated in this order formed on both surfaces of the resin substrate, the resin, or the prepreg as the center; a laminated material containing structures each containing “release layer/barrier layer/copper foil/resin substrate or resin or prepreg/release layer/barrier layer/copper foil” laminated in this order on the both surfaces; a laminated material containing structures each containing “release layer/barrier layer/copper foil/resin substrate/release layer/barrier layer/copper foil” laminated in this order on the both surfaces; or a laminated material containing structures each containing “copper foil/barrier layer/release layer/resin substrate/release layer/barrier layer/copper foil” laminated in this order on the both surfaces may be used in the aforementioned production method of a printed wiring board (core-less process). On the copper foil on both ends of the laminated material or on the exposed surface of the release layer, another resin layer may be provided, and further thereon a copper layer or a metal layer may be formed and then processed to form a circuit or a wiring. Furthermore, another resin layer may be provided on the circuit or the wiring, so as to embed (bury) the circuit or the wiring. On the copper foil on both ends of the laminated material or on the exposed surface of the release layer, a wiring or a circuit of copper or a metal may be provided, and another resin layer may be provided on the wiring or the circuit, so as to embed (bury) the wiring or the circuit in the another resin. Thereafter, on the another resin layer, a circuit or a wiring and a resin layer may be formed. The formation of the circuit or the wiring and the resin layer may be performed one or more times (i.e., a buildup process). In the laminated material thus formed (which may be hereinafter referred to as a laminated material B), the copper foils with a release layer may be released from the laminated material, thereby producing a core-less substrate. In the production of the core-less substrate, the laminated material having a structure containing copper foil/barrier layer/release layer/release layer/barrier layer/copper foil, the laminated material having a structure containing release layer/barrier layer/copper layer/copper layer/barrier layer/release layer, or the laminated material having a structure containing release layer/barrier layer/copper foil/release layer/barrier layer/copper foil, described later, may be produced by using two copper foils with a release layer, and the laminated material may be used as the center. On the surfaces of the copper foil or the release layer on both sides of the laminated material (which may be hereinafter referred to as a laminated material A), two layers of a resin layer and a circuit may be provide one or more times, and after providing the two layers of the resin layer and the circuit one or more times, the layer having the two layers of the resin layer and the circuit provided one or more times may be released from each of the copper foils with a release layer, thereby producing a core-less substrate. The two layers of the resin layer and the circuit may be provided in the order of the resin layer and the circuit, and may be provided in the order of the circuit and the resin layer. The laminated material may have another layer on the surface of the copper foil, on the surface of the release layer, between the release layer and the release layer, between the copper foil and the copper foil, and between the copper foil and the release layer. The another layer may be a resin substrate or a resin layer. In the description herein, in the case where the copper foil, the release layer, and the laminated material have another layer on the copper foil surface, the release layer surface, or the laminated material surface, the “surface of the copper foil”, the “surface on the side of the copper foil”, the “copper foil surface”, the “surface of the release layer”, the “surface on the side of the release layer”, the “release layer surface”, the “surface of the laminated material”, and the “laminated material surface” each have a concept that includes the surface (outermost surface) of the another layer. The laminated material preferably has a structure containing copper foil/barrier layer/release layer/release layer/barrier layer/copper foil. This is since in the production of a core-less substrate by using the laminated material, the copper foil is disposed on the side of the core-less substrate, and thus a circuit can be easily formed on the core-less substrate by the modified semi-additive method. This is also since in the case where the thickness of the copper foil is small, the copper foil can be easily removed, and a circuit can be easily formed on the core-less substrate by the semi-additive method after removing the copper foil.

In the description herein, the “laminated material” that is not defined as to whether it is the “laminated material A” or the “laminated material B” means a laminated material that includes at least the laminated material A and the laminated material B.

In the aforementioned production method of a core-less substrate, apart or the whole of the end surface of the copper foil with a release layer or the laminated material (including the laminated material A) may be covered with a resin, whereby in the production of a printed wiring board by the buildup method, chemicals can be prevented from invading into between the release layer or one of the copper foil with a release layer constituting the laminated material and the other one of the copper foil with a release layer, and thereby the corrosion of the copper foils with a release layer due to the invasion of the chemicals can be prevented, so as to enhance the yield. The “resin covering a part or the while of the end surface of the copper foil with a release layer” or the “resin covering apart or the whole of the end surface of the laminated material” used may be a resin that can be used in the resin layer or a known resin. In the aforementioned production method of a core-less substrate, at least the outer periphery of the laminated portion of the copper foil with a release layer or the laminated material in planar view of the copper foil with a release layer or the laminated material (i.e., the laminated portion of the release layer and the copper foil, or the laminated portion of one of the copper foil with a release layer and the other one of the copper foil with a release layer) may be covered with a resin or a prepreg. The laminated material formed in the production method of a core-less substrate (i.e., the laminated material A) may be constituted by making a pair of the copper foils with a release layer in contact with each other separably. In the planar view of the copper foil with a release layer, the whole of the outer periphery of the laminated portion of the copper foil with a release layer or the laminated material (i.e., the laminated portion of the release layer and the copper foil, or the laminated portion of one of the copper foil with a release layer and the other one of the copper foil with a release layer) or the entire surface of the laminated portion may be covered with a resin or a prepreg. In the planar view, furthermore, the resin or the prepreg is preferably larger than the laminated portion of the copper foil with a release layer, the laminated material, or the laminated material, and it is preferred that the resin or the prepreg is laminated on both surfaces of the copper foil with a release layer or the laminated material, so as to provide a laminated material having such a structure that the copper foil with a release layer or the laminated material is encapsulated (enveloped) with the resin or the prepreg. According to the structure, in the planar view of the copper foil or the laminated material, the laminated portion of the copper foil with a release layer or the laminated material is covered with the resin or the prepreg, whereby another member can be prevented from being in contact with the side portion thereof, i.e., in contact therewith in the lateral direction with respect to the lamination direction, and consequently the release between the release layer and the copper foil or between the copper foils with a release layer during the handling can be suppressed. By covering the outer periphery of the laminated portion of the copper foil with a release layer or the laminated material with the resin or the prepreg for preventing them from being exposed, chemicals can be prevented from invading into the interfaces of the laminated portion in the chemical processing step, as described above, and thus the copper foil with a release layer can be prevented from being corroded or etched. In the case where the laminated portion of the copper foil with a release layer or the laminated material covered with the resin or the prepreg (i.e., the laminated portion of the release layer and the copper foil, or the laminated portion of one of the copper foil with a release layer and the other one of the copper foil with a release layer) is firmly adhered to the resin, the prepreg, or the like, there may be a case where the laminated portion or the like is necessarily removed by cutting or the like on separating one of the copper foil with a release layer from the pair of the copper foils with a release layer of the laminated material.

The side of the release layer or the side of the copper foil of the copper foil with a release layer of the invention may be laminated on the side of the release layer or the side of another one of the copper foil of the copper foil with a release layer of the invention, so as to constitute a laminated material. The surface on the side of the release layer or the surface on the side of the copper foil of the one of the copper foil with a release layer and the surface on the side of the release layer or the surface on the side of the copper foil of the another one of the copper foil with a release layer may be directly laminated, depending on necessity with an adhesive, so as to provide a laminated material. The release layer or the copper foil of one of the copper foil with a release layer and the release layer or the copper foil of another one of the copper foil with a release may be bonded. In the case where the release layer or the copper foil has a surface treatment layer, the “bonded” herein includes an embodiment where they are bonded to each other through the surface treatment layer. Apart or the whole of the end surface of the laminated material may be covered with a resin.

The lamination of the release layers to each other, the copper foils to each other, the release layer and the copper layer, and the copper foils with a release layer to each other may be performed, for example, in the following manners, in addition to simply superimposing:

(a) metallurgical bonding method: fusion welding (e.g., arc welding, TIG (tungsten inert gas) welding, MIG (metal inert gas) welding, resistance welding, seam welding, and spot welding), pressure welding (e.g., ultrasonic welding and friction stir welding), and brazing;

(b) mechanical bonding method: crimping, bonding with rivet (e.g., bonding with self-piercing rivet and bonding with rivet), and stitcher; and

(c) physical bonding method: adhesive and (double-sided) adhesive tape.

One of the copper foil may be laminated on the other one of the copper foil or the release layer by bonding a part or the whole of one of the copper foil to a part or the whole of other one of the copper foil or apart or the whole of the release layer by the aforementioned bonding method, so as to produce a laminated material having a structure that the one of copper foils or the other copper foil and the release layer are in contact with each other separably. In the case where one of the copper foil is laminated on the other one of the copper foil or the release layer in such a manner that one of the copper foil is weakly bonded to the other one of the copper foil or the release layer, one of the copper foil and the other one of the copper foil or the release layer can be released from each other without removal of the bonded portion of one of the copper foil and the other one of the copper foil or the release layer. In the case where one of the copper foil is firmly bonded to the other one of the copper foil or the release layer, one of the copper foil and the other one of the copper foil or the release layer can be released from each other by removing the bonded portion of one of the copper foil and the other one of the copper foil or the release layer by such a manner as cutting, chemical grinding (e.g., etching), mechanical grinding, or the like.

A printed wiring board having no core can be produced by performing a step of providing two layers of a resin layer and a circuit on the thus-constituted laminated material at least one time, and a step of after forming the two layers of the resin layer and the circuit at least one time, releasing a layer containing the two layers of the resin layer and the circuit formed at least one time, from the copper foil with a release layer of the laminated material. The two layers of the resin layer and the circuit may be provided on one or both surfaces of the laminated material. The two layers of the resin layer and the circuit may be provided in the order of the resin layer and the circuit, and may be provided in the order of the circuit and the resin layer.

The resin substrate, the resin layer, the resin, and the prepreg used in the aforementioned laminated material may be the resin layer described in the description herein, and may contain the resin, the resin curing agent, the compound, the curing accelerator, the dielectric material, the reaction catalyst, the crosslinking agent, the polymer, the prepreg, the aggregate, and the like used in the resin layer described in the description herein.

The copper foil with a release layer or the laminated material may be smaller than the resin, the prepreg, the resin substrate, or the resin layer in planar view.

### EXAMPLES

The invention will be described in more detail with reference to examples of the invention below, but the invention is not limited to the examples.

### Example 1: Copper Foil with Release Layer

The copper foil used was an electrolytic copper foil, JTC Foil (thickness: 35 μm), produced by JX Nippon Mining & Metals Corporation, and on the S surface (gloss surface) of the electrolytic copper foil, a Ni layer having a thickness of 1 μm was formed as a barrier layer by electroplating under the following conditions.

### Nickel (Ni) Plating

Plating Solution
Nickel: 20 to 200 g/L
Boric acid: 5 to 60 g/L
Liquid temperature: 40 to 65° C.
pH: 1.5 to 5.0

Current density: 0.5 to 20 A/dm²

Energizing time: 1 to 20 seconds

Agitation (circulated liquid amount): 100 to 1,000 L/min

Conveying speed: 2 to 30 m/min

Additives: primary gloss agent (sodium saccharin: 0.5 to 5 g/L), secondary gloss agent (thiourea: 0.05 to 1 g/L)

Thereafter, a release layer was formed on the Ni layer under the following conditions.

### Silane Coupling Treatment

Treating Solution
Silane compound: n-propyltrimethoxysilane
Silane concentration: 0.4% by volume
Agitation time of treating solution before use: 12 hours
Alcohol concentration: 0% by volume
(balance of water)
pH: 4 to 7

Treating time: 30 seconds (coating with spray nozzle)

### Example 2: Copper Foil with Release Layer

The copper foil used was an electrolytic copper foil, JTC Foil (thickness: 35 μm), produced by JX Nippon Mining & Metals Corporation, and on the S surface (gloss surface) of the electrolytic copper foil, a Ni—Cr alloy layer having a thickness of 0.1 μm was formed as a barrier layer by sputtering under the following conditions.

### Ni—Cr Alloy Dry Plating

Sputtering Target
Composition: Ni-20% by weight Cr

Sputtering Device
Sputtering device, produced by Ulvac, Inc.

Sputtering Condition
Output power: DC 50 W
Argon pressure: 0.2 Pa

Thereafter, a release layer was formed on the Ni—Cr alloy layer under the following conditions.

Surface Treatment with Compound Having Two or Less Mercapto Groups in Molecule

Treating Solution
Compound having two or less mercapto groups in molecule: sodium 1-dodecanethiolsulfonate
Concentration of compound having two or less mercapto groups in molecule: 3% by weight
(balance of water)
pH: 5 to 9

Treating time: 60 seconds (coating with spray nozzle)

After the treatment, the coated solution was dried in the air at 100° C. for 5 minutes to form a release layer.

### Example 3: Copper Foil with Release Layer

The copper foil used was an electrolytic copper foil, JTC Foil (thickness: 35 μm), produced by JX Nippon Mining & Metals Corporation, and on the S surface (gloss surface) of the electrolytic copper foil, an Al layer having a thickness of 0.5 μm was formed as a barrier layer by sputtering under the following conditions.

### Al Dry Plating

Sputtering Target
Composition: Al 99% by mass or more

Sputtering Device
Sputtering device, produced by Ulvac, Inc.

Sputtering Condition
Output power: DC 50 W
Argon pressure: 0.2 Pa

Thereafter, a release layer was formed on the Al layer under the following conditions.

Surface Treatment with Metal Alkoxide

Treating Solution
Metal alkoxide: triisopropoxyaluminum as aluminate compound
Concentration of aluminate compound: 0.04 mol/L
(balance of water)
pH: 5 to 9

Treating time: 45 seconds (coating with spray nozzle)

Agitation time from dissolution of aluminate compound in water to coating: 2 hours

Alcohol concentration in aqueous solution: 0% by volume

After the treatment, the coated solution was dried in the air at 100° C. for 5 minutes to form a release layer.

### Example 4: Copper Foil with Release Layer

The copper foil used was an electrolytic copper foil, JTC Foil (thickness: 12 μm), produced by JX Nippon Mining & Metals Corporation, and on the S surface (gloss surface) of the electrolytic copper foil, a Co layer having a thickness of 2 μm was formed as a barrier layer by electroplating under the following conditions.

### Cobalt (Co) Plating

Plating Solution
Cobalt: 20 to 200 g/L
Boric acid: 5 to 60 g/L
Liquid temperature: 40 to 65° C.
pH: 1.5 to 5.0

Current density: 0.5 to 20 A/dm²

Energizing time: 1 to 20 seconds

Agitation (circulated liquid amount): 100 to 1,000 L/min

Conveying speed: 2 to 30 m/min

Additives: primary gloss agent (sodium saccharin: 0.5 to 5 g/L), secondary gloss agent (thiourea: 0.05 to 1 g/L)

Thereafter, a release layer was formed on the Co layer under the following conditions.

Surface Treatment with Metal Alkoxide

Treating Solution
Metal alkoxide: n-propyl-tri-n-butoxyzirconium as zirconate compound
Concentration of zirconate compound: 0.04 mol/L
(balance of water)
pH: 5 to 9

Treating time: 30 seconds (coating with spray nozzle)

Agitation time from dissolution of zirconate compound in water to coating: 12 hours

Alcohol concentration in aqueous solution: 0% by volume

After the treatment, the coated solution was dried in the air at 100° C. for 5 minutes to form a release layer.

### Example 5: Copper Foil with Release Layer

The copper foil used was an electrolytic copper foil, JTC Foil (thickness: 9 μm), produced by JX Nippon Mining & Metals Corporation, and on the S surface (gloss surface) of the electrolytic copper foil, a Cr layer having a thickness of 0.2 μm was formed as a barrier layer by electroplating under the following conditions.

### Chromium (Cr) Plating

Plating Solution
CrO₃: 200 to 400 g/L
H₂SO₄: 1.5 to 4 g/L
Liquid temperature: 40 to 65° C.
pH: 1 to 4

Current density: 10 to 40 A/dm²

Energizing time: 1 to 20 seconds

Agitation (circulated liquid amount): 100 to 1,000 L/min

Conveying speed: 2 to 30 m/min

Thereafter, a release layer was formed on the Cr layer under the following conditions.

Surface Treatment with Metal Alkoxide

Treating Solution
Metal alkoxide: n-decyl-triisopropoxytitanium as titanate compound
Concentration of titanate compound: 0.01 mol/L
(balance of water)
pH: 5 to 9

Treating time: 15 seconds (coating with spray nozzle)

Agitation time from dissolution of titanate compound in water to coating: 24 hours

Alcohol concentration in aqueous solution: methanol 20% by volume

After the treatment, the coated solution was dried in the air at 100° C. for 5 minutes to form a release layer.

### Test Results

Embedded circuit boards (printed wiring boards) were able to be produced as shown in FIGS. 1a-1i by using the copper foils with a release layer of Examples 1 to 5, Prepreg FR-4 as the resin laminated on the copper foil on the side of the barrier layer, and an epoxy resin as the embedding resin.

In Example 1, the circuit was formed by etching the copper foil with Mecbrite SF-5420, an etching solution produced by MEC Co., Ltd. In Example 1, the barrier layer was removed with MEC Remover NH-1860 Series, an etching solution produced by MEC Co., Ltd.

In Example 2, the circuit was formed by etching the copper foil with Copper selective etching solution CSS, produced by Nihon Kagaku Sangyo Co., Ltd. In Example 2, the barrier layer was removed with MEC Remover CH Series, an etching solution produced by MEC Co., Ltd.

In Example 3, the circuit was formed by etching the copper foil with a selective etching solution produced by MEC Co., Ltd. In Example 3, the barrier layer was removed with MEC Albrite AS-1250, an etching solution produced by MEC Co., Ltd.

In Example 4, the circuit was formed by etching the copper foil with a selective etching solution produced by MEC Co., Ltd. In Example 4, the barrier layer was removed with MEC Remover S651A, a selective etching solution produced by MEC Co., Ltd.

In Example 5, the circuit was formed by etching the copper foil with an aqueous solution having ferric chloride and hydrochloric acid dissolved in water as an etching solution. In Example 5, the barrier layer was removed with an alkaline chromium etching solution, produced by Nihon Kagaku Sangyo Co., Ltd.

1. A copper foil with a release layer, comprising, in this order, a release layer; a barrier layer having dissolution resistance to a copper etchant; and a copper foil.

2. The copper foil with a release layer according to claim 1, wherein the barrier layer having dissolution resistance to a copper etchant is a layer having one or more layers selected from the group consisting of a Ni layer, a Ti layer, a Cr layer, a V layer, a Zr layer, a Ta layer, an Au layer, a Pt layer, an Os layer, a Pd layer, a Ru layer, a Rh layer, an Ir layer, a W layer, a Sn layer, a stainless steel layer, an Ag layer, a Mo layer, a Ni—Cr alloy layer, an Al layer, a Co layer, an In layer, a Bi layer, an ITO (indium tin oxide) layer; a layer containing an alloy containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, B Sn, Ag, Mo, and Cr; and a layer containing a carbide, an oxide, or a nitride containing one or more element selected from the group consisting of Ni, Ti, V, Zr, Ta, Au, Pt, Os, Pd, Ru, Rh, Ir, W, Si, Fe, Mo, Mn, P, S, N, C, Al, Co, In, Bi, Sn, Ag, Mo, and Cr.

3. The copper foil with a release layer according to claim 1, wherein the barrier layer having dissolution resistance to a copper etchant is a Ni layer or an alloy layer containing Ni.

4. The copper foil with a release layer according to claim 1, wherein the release layer comprises a silane compound represented by the following formula, a hydrolyzed product thereof, or a condensed product of the hydrolyzed product alone or in combination thereof: 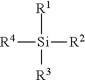
wherein R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; and R³ and R⁴ each independently represents a halogen atom, or an alkoxy group, a hydrocarbon group selected from the group consisting of an alkyl group, a cycloalkyl group, and an aryl group, or any of the hydrocarbon groups with at least one hydrogen atom substituted with a halogen atom.

5. The copper foil with a release layer according to claim 1, wherein the release layer comprises a compound having two or less mercapto groups in a molecule.

6. The copper foil with a release layer according to claim 1, wherein the release layer comprises a single compound or a combination of plural compounds of an aluminate compound, a titanate compound, or a zirconate compound represented by the following formula, a hydrolyzed product thereof, or a condensed product of the hydrolyzed product:
(R¹)ₘ-M-(R²)ₙ
wherein R¹ represents an alkoxy group or a halogen atom; R² represents a hydrocarbon group selected from the group consisting of an alkyl group, a cycloalkyl group, and an aryl group, or any of the hydrocarbon groups with at least one hydrogen atom substituted with a halogen atom; M represents any one of Al, Ti, and Zr; n represents 0, 1, or 2; and m represents an integer of 1 or more and a valence of M or less, provided that at least one of R¹ represents an alkoxy group, and m+n is a valence of M.

7. The copper foil with a release layer according to claim 1, wherein the release layer has a resin coated film constituted by one or more resins selected from the group consisting of a silicone, an epoxy resin, a melamine resin, and a fluorine resin.

8. The copper foil with a release layer according to claim 1, wherein the copper foil comprises one or more layers selected from the group consisting of a roughening treatment layer, a heat resistant layer, a rust preventing layer, a chromate treatment layer, and a silane coupling treatment layer, on a surface opposite to the release layer.

9. The copper foil with a release layer according to claim 8, wherein the roughening treatment layer is a layer containing a single material selected from the group consisting of copper, nickel, phosphorus, tungsten, arsenic, molybdenum, chromium, titanium, iron, vanadium, cobalt, and zinc, or an alloy containing one or more thereof.

10. The copper foil with a release layer according to claim 8, wherein the copper foil comprises a resin layer, on the one or more layers selected from the group consisting of a roughening treatment layer, a heat resistant layer, a rust preventing layer, a chromate treatment layer, and a silane coupling treatment layer.

11. The copper foil with a release layer according to claim 1, wherein the copper foil with a release layer has a resin layer, on the copper foil.

12. A laminated material comprising the copper foil with a release layer according to claim 1.

13. A laminated material comprising the copper foil with a release layer according to claim 1 and a resin, a part or the whole of an end surface of the copper foil with a release layer being covered with the resin.

14. A laminated material comprising two copper foils with a release layer according to claim 1 and a resin, the resin being provided in such a manner that a surface of one copper foil with a release layer of the two copper foils with a release layer on the side of the copper foil and a surface of the other copper foil with a release layer thereof on the side of the copper foil each are exposed.

15. A laminated material comprising one of the copper foil with a release layer according to claim 1, being laminated on the side of the copper foil of another copper foil with a release layer according to claim 1.

16. A method for producing a printed wiring board, comprising producing a printed wiring board by utilizing the copper foil with a release layer according to claim 1.

17. A method for producing a printed wiring board, comprising:
laminating a first insulating substrate on the copper foil with a release layer according to claim 1, on the side of the release layer;
laminating a dry film on the copper foil with a release layer of the invention having the first insulating substrate laminated thereon, on the side of the copper foil;
patterning the dry film, and then etching the copper foil, so as to form a circuit;
releasing the dry film, so as to expose the circuit;
covering the exposed circuit with a second insulating substrate, so as to embed the circuit;
releasing the first insulating substrate from a laminated material of the circuit embedded in the second insulating substrate and a barrier layer, through the release layer, so as to expose the barrier layer; and
removing the exposed barrier layer by etching, so as to expose the circuit embedded in the second insulating substrate.

18. A method for producing an electronic apparatus, comprising producing an electronic apparatus by utilizing a printed wiring board produced by the method according to claim 16.

19. A method for producing an electronic apparatus, comprising producing an electronic apparatus by utilizing a printed wiring board produced by the method according to claim 17.
